(19) United States
(12) Patent Application Publication
(10) Pub. No.: US 2001/0050404 A1
(43) Pub. Date: Dec. 13, 2001

(54) Solar cell and method of manufacturing the same

(75) Inventors: Yoshimitsu Saito, Saitama (JP); Seiichi Yokoyama, Saitama (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(73) Assignee: Honda Giken Kogyo Kabushiki Kaisha, Tokyo (JP)

(21) Appl. No.: 09/867,444

(22) Filed: May 31, 2001

(30) Foreign Application Priority Data
Jun. 2, 2000 (JP) 2000-165757
May 14, 2001 (JP) 2001-143068

(51) Int. Cl. H01L 21/00; H01L 31/06

(52) U.S. Cl. 257/461; 438/73; 438/72; 438/98; 257/464

(57) ABSTRACT

The present invention provide a solar cell and a method of manufacturing the same which is high in the efficiency of energy conversion and improved in the durability while its production process requires not particularly high accuracy.

Its substrate 1 is substantially an n− layer of which the main or light incident surface has an intermediate energy level layer 2 provided therein including an electron trap. An antireflection coating 15 is provided on the surface of the intermediate energy level layer 2. The substrate 1 has n+ region 6 and p+ region 9 provided in the other or back surface thereof. The n+ and p+ semiconductor regions 6 and 9 are connected with external electrodes 14n and 14p respectively. The remaining of the back surface of the substrate 1 where the external electrodes 14n and 14p are not provided is covered with an oxide film.

### BACKGROUND OF THE INVENTION

1. Field of the Invention

The present invention relates to a solar cell and a method of manufacturing the same where a technique of two-step light excitation through an intermediate energy level generated in an energy band gap (may be referred to as the effect of intermediate energy level hereinafter) is used for improving the efficiency of energy conversion.

2. Description of the Related Art

One of technologies for improving the efficiency of energy conversion in a solar cell is disclosed in Japanese Patent Laid-open Publication (Heisei)8-250755 which utilizes the effect of intermediate energy level. FIG. 11 illustrates the principles of the effect of intermediate energy level where an electron trap Tr having an intermediate energy level (Etr) higher than energy level Ev at the surface of a valence band but lower than energy level Ec at the bottom of a conduction band is developed in an forbidden band or the energy band gap.

A conventional structure having no electron trap in the forbidden band permits a limited wavelength range of light having an energy exceeding (Ec-Ev) to contribute to the generation of electricity. Using the effect of intermediate energy level, the two-step light excitation across the electron trap Tr can encourage an extra wavelength range of light having an energy lower than (Ec-Ev) to be converted to electric energy.

Such a solar cell using the effect of intermediate energy level is disclosed in U.S. Pat. No. 6,130,380 as shown in FIG. 12 where its structure has an n+ diffused layer 51 and a p+ diffused layer 52 provided on the back side opposite to the light incident surface thereof as well as an intermediate energy level layer 53 with the electron trap Tr provided in a near-surface area of the back side thereof where the diffused layers 51 and 52 are absent. The electron trap Tr is generated by a defect layer or an amorphous layer formed by known ion implantation.

In the solar cell structure shown in FIG. 12, a light energy which exceeds the band gap energy is absorbed in the intrinsic or p− layer 54 in its light incident side where it excites carries to move directly to the n+ diffused layer 51 and the p+ diffused layer 52 without passing the intermediate energy level layer 53. On the other hand, a light energy which is lower than the band gap energy is absorbed in the intermediate energy level layer 53 and excites carriers to move in the intermediate energy level layer 53 to the n+ diffused layer 51 and the p+ diffused layer 52.

As the electron trap Tr functions as a center region for recombining the carriers, it has to be precisely located in the depletion layer between the p and n regions in the conventional technology disclosed in the Publication (Heisei)8-250755 as shown in FIG. 11. It is hence essential for forming the electron trap at a precise location in the depletion layer between the p and n regions to use a highly accurate level of the manufacturing process.

Also, the defect layer or amorphous layer acting as the electron trap disclosed in U.S. Pat. No. 6,130,380 is low in the physical stability and may be unfavorable to act a part in a device, such as a solar cell, installed in the outdoor for a considerable duration of time. The defect layer may hardly be formed at higher repeatability and may be low in the controllability, thus being unfavorable in mass production.

As the defect layer or amorphous layer as the electron trap is eliminated by heating up during the formation of the n+ diffused layer 51 and the p+ diffused layer 52, it has to be formed after the formation of the diffused layers 51 and 52. This requires an extra step of selectively masking the diffused layers 51 and 52 for protection prior to the formation of the intermediate energy level layer 53 in the prior art, hence increasing the overall number of manufacturing steps.

Still more, the light energy lower than the band gap energy is not available for energy conversion at the n+ and p+ diffused layers.

In the conventional solar cell shown in FIG. 12, the carriers travel a quite distance from the intermediate energy level layer 53 to the n+ diffused layer 51 and the p+ diffused layer 52 and may thus be lost at higher probability by recombination.

### SUMMARY OF THE INVENTION

It is an object of the present invention to provide a solar cell and a method of manufacturing the same which is high in the efficiency of energy conversion and improved in the durability while its production process requires not particularly high accuracy.

According to the present invention, a solar cell having a light incident surface at one side of a semiconductor substrate is provided with the following features:

(1) An intermediate energy level layer having electron traps therein is formed over the light incident surface and semiconductor regions of a first conductive type and a second conductive type are formed in the other side of the semiconductor substrate.

(2) Semiconductor regions of a first conductive type and a second conductive type are formed in the other side of the semiconductor substrate and an intermediate energy level layer having electron traps therein is formed over the other side of the semiconductor substrate, wherein the intermediate energy level layer is an impurity doped layer.

(3) separating means are provided for separating the intermediate energy level layer between the semiconductor regions of the first conductive type and the second conductive type.

As defined in the feature (1), a portion of light having an energy lower than the band gap energy is absorbed in the intermediate energy level layer on the light incident side where it excites carriers to move in a direction vertical to the substrate from the intermediate energy level layer to the semiconductor regions. This can minimize the distance of movement of the carriers across the intermediate energy level layer, thus lowering the probability of recombination of the carriers in the intermediate energy level layer. Still more, the light energy which exceeds the band gap energy is generally absorbed in the substrate 1 where it excites carriers to move directly to the n+ region 6 and the p+ region 9 without passing across the intermediate energy level layer 2. Accordingly, the loss of the carrier by recombination will significantly be reduced.

As defined in the feature (2), the intermediate energy level layer is impurity layer so that when located on the same plane as of the n+ regions and the p+ regions, the intermediate energy level layer can extend throughout the surface of the substrate before the semiconductor regions are formed. This allows the intermediate energy level layer to be manufacturing without masks, thus simplifying the overall procedure of the fabrication and contributing to the less complex production of highly durable solar cells.

As defined in the feature (3), the intermediate energy level layer does not act as a passage of leak current between the first conductive type semiconductor region and the second conductive type semiconductor region and when the intermediate level density in the intermediate energy level layer is increased, it will hardly permit escape of the leak current.

### BRIEF DESCRIPTION OF THE DRAWINGS

FIG. 1 is a cross sectional view of a first embodiment of the present invention;

FIG. 2 is a cross sectional view illustrating the mechanism of the first embodiment;

FIGS. 3A to 3O are cross sectional views illustrating a procedure of manufacturing the first embodiment;

FIG. 4 is a cross sectional view of a second embodiment of the present invention;

FIGS. 5A to 5O are cross sectional views illustrating a procedure of manufacturing the second embodiment;

FIG. 6 is a table showing the comparison in performance between a second embodiment and the prior art;

FIG. 7 is a diagram showing the comparison between the output characteristic and the current characteristic of the second embodiment.

FIG. 8 is a diagram showing the comparison between the output characteristic and the current characteristic of a third embodiment.

FIG. 9 is a cross sectional view of the third embodiment of the present invention;

FIGS. 10A to 10R are cross sectional views illustrating a procedure of manufacturing the third embodiment;

FIG. 11 is a diagram illustrating the principles of the effect of intermediate energy level; and

FIG. 12 is a cross sectional view of a prior art.

### DETAILED DESCRIPTION OF THE PREFERRED EMBODIMENTS

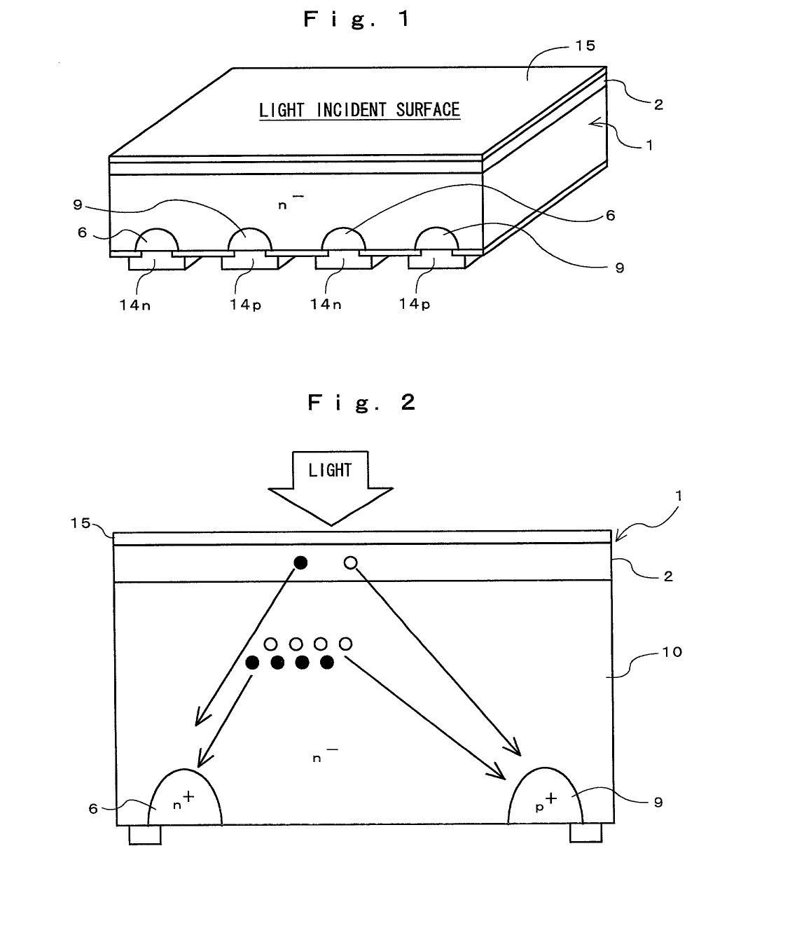

FIG. 1 is a perspective view of a cross sectional structure of a solar cell showing a first embodiment of the present invention.

The substrate 1 is substantially an n− layer of which the main or light incident surface has an intermediate energy level layer 2 provided therein including an electron trap. An antireflection coating 15 is provided on the surface of the intermediate energy level layer 2. The substrate 1 has n+ region 6 and p+ region 9 provided in the other or back surface thereof. The semiconductor regions 6 and 9 are connected with external electrodes 14n and 14p respectively. The remaining of the back surface of the substrate 1 where the external electrodes 14n and 14p are not provided is covered with an oxide film.

FIG. 2 is a cross sectional view schematically showing the principles of mechanism of the first embodiment.

A light energy incident on the light incident surface which is lower than the band gap energy is absorbed in the intermediate energy level layer 2 where it excites carriers to move in a direction vertical to the substrate from the intermediate energy level layer 2 via an n− layer 10 to the n+ regions 6 or the p+ regions 9. This allows the movement of the carriers in the intermediate energy level layer 2 to be shorter than that of the prior art, hence minimizing the loss of the carriers by recombination.

The remaining portion of incident light having an energy which exceeds the band gap energy is generally absorbed in the n− layer 10 of the substrate 1 where it excites carriers to travel directly to the n+ regions 6 or the p+ regions 9 without passing through the intermediate energy level layer 2. As a result, the carriers excited in the n− layer 10 will be prevented from being lost by recombination in the intermediate energy level layer 2.

This embodiment inhibits not only the carriers excited by the light energy exceeding the band gap energy but also the carriers excited by the light energy lower than the band gap energy from being lost by recombination in the intermediate energy level layer 2, thus improving the efficiency of energy conversion in the solar cell.

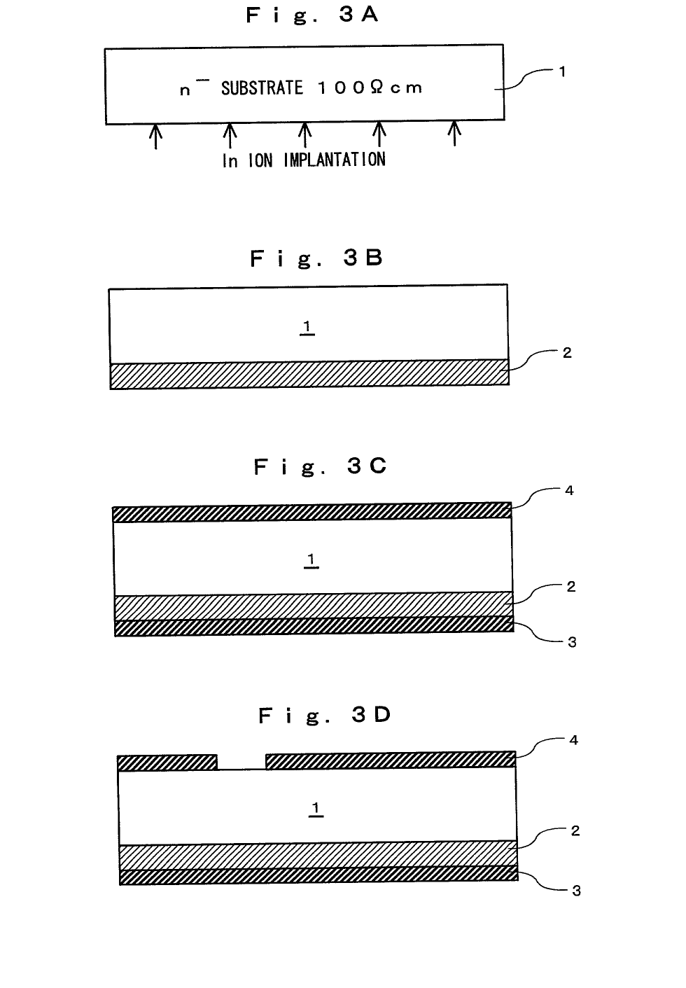

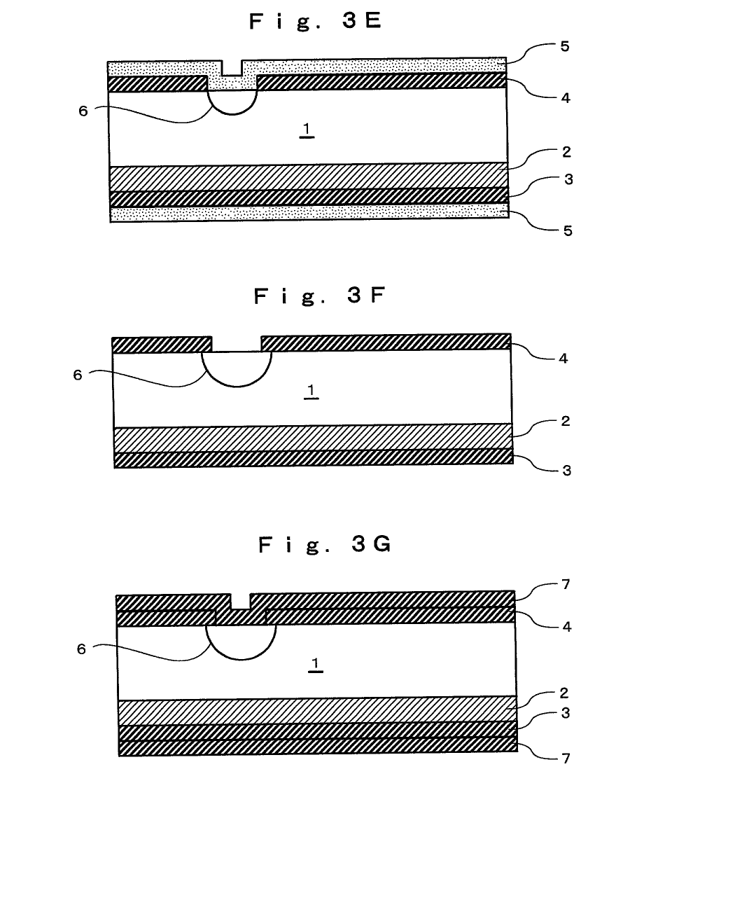

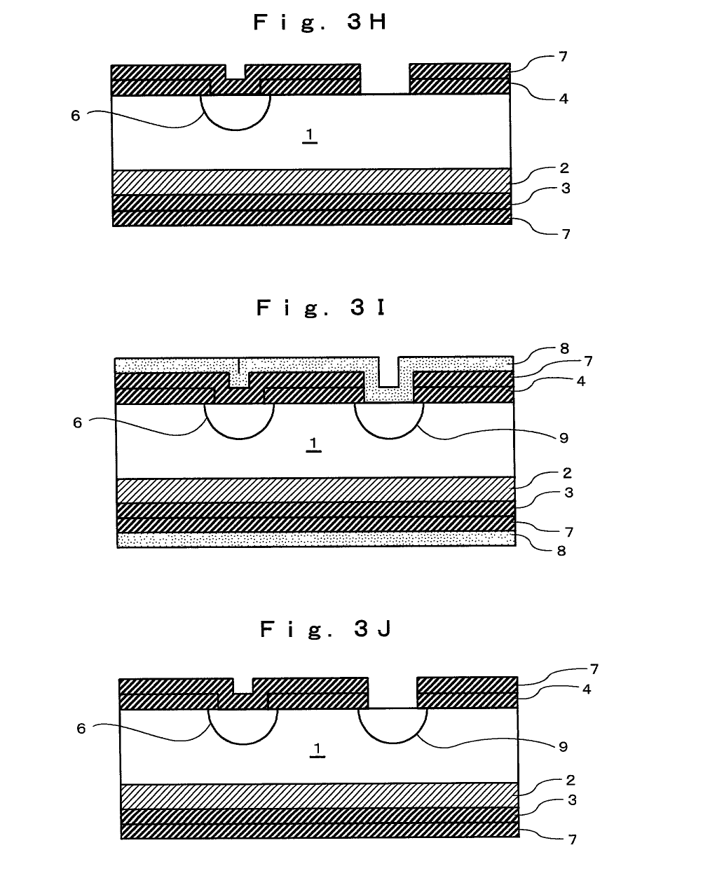

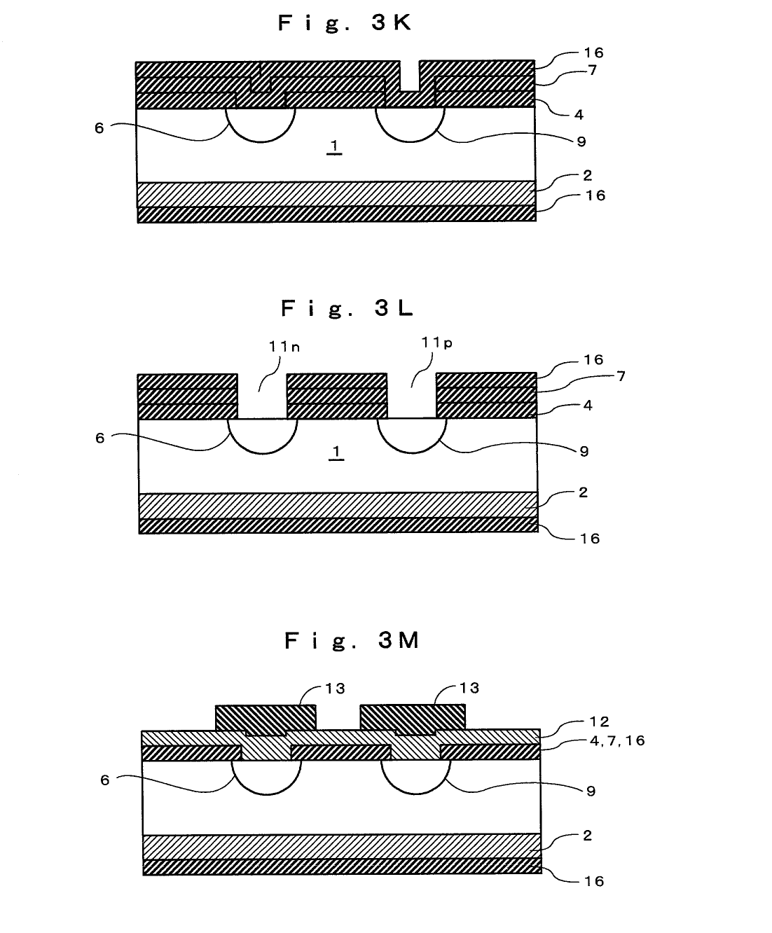

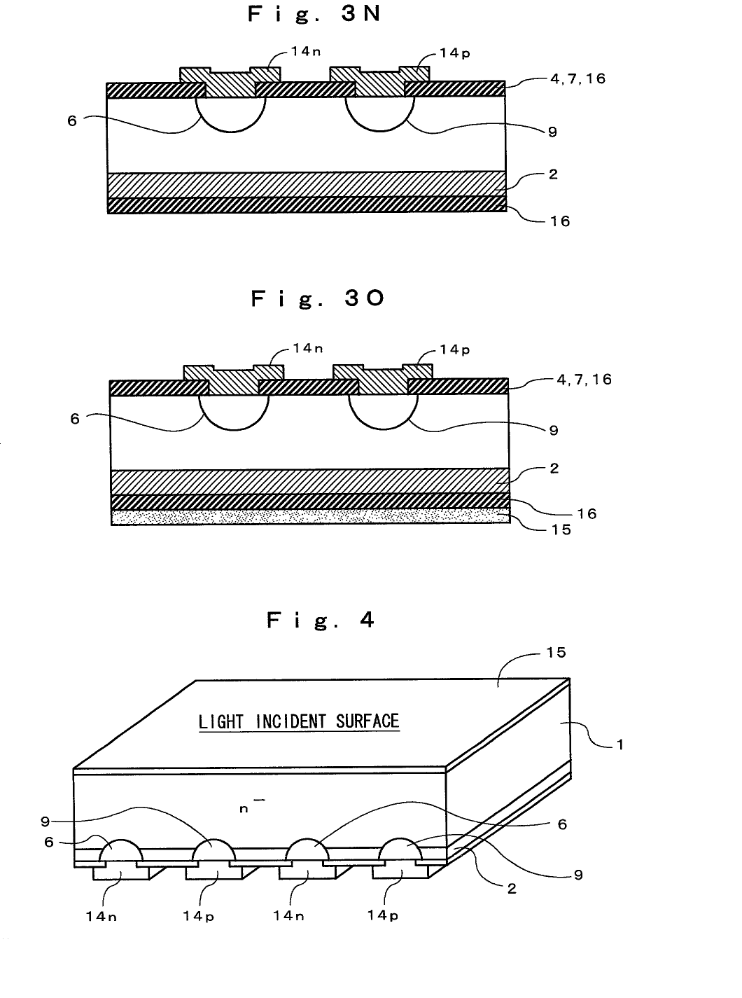

A method of manufacturing the solar cell of the first embodiment will now be described referring to the cross sectional views of FIGS. 3A-3O.

(1) An n− substrate 1 of 100 Ωcm is doped at 180 KV by ion implantation of In of 1E13 cm⁻² (FIG. 3A) and annealed for activation at 1100° C. for two hours to form an intermediate energy level layer 2 in the light incident side thereof (FIG. 3B).

(2) Thermally oxidized SiO₂ layers 3 and 4 are formed to 500 angstroms on the light incident side and the back side of the substrate 1 respectively (FIG. 3C) and a patterned photoresist is provided on the back side (not shown). This is followed by wet etching the SiO₂ layer 4 to remove desired portions which will be the n+ regions later (FIG. 3D). At the time, the light incident side remains protected with a film of photoresist (not shown). After the wet etching, all the photoresists are then removed.

(3) A layer of phosphosilicate glass 5 is deposited at 950° C. (FIG. 3E) to diffuse phosphorus to the substrate 1. While the phosphosilicate glass layer 5 is removed using an HF etching solution, its phosphorus is thermally diffused in at 1000° C. to form n+ regions 6 (FIG. 3F).

(4) Under the same conditions as for forming of the n+ regions 6, Thermally oxidized SiO₂ layers 7 are formed to 500 angstroms on both the sides (FIG. 3G). After a pattern of photoresist is provided (not shown), the two SiO₂ layers 4 and 7 are wet etched to remove desired portions which will be the p+ regions later (FIG. 3H). At the time, the light incident side remains protected with a film of photoresist (not shown). After the wet etching, all the photoresists are then removed.

(5) A layer of borosilicate glass 8 is deposited at 900° C. and its boron is thermally diffused in at 1000° C. to form p+ regions 9 in the substrate 1 (FIG. 3I). The borosilicate glass layer 8 is removed using the HF etching solution (FIG. 3J).

(6) The back side is also protected with a film of photoresist (not shown). The two SiO₂ layers 3 and 7 on the light incident side are removed by wet etching with the HF etching solution and then, the photoresist is removed. This is followed by forming on both the sides thermally oxidized SiO₂ layer 16 to 300 angstroms (FIG. 3K)

(7) A pattern of photoresist is provided on the back side for positioning contact holes 11n and 11p (not shown) The SiO₂ layer 16,7,4 on the back side is partially removed by wet etching. At the time, the light incident side remains protected with a film of photoresist (not shown). The photoresist is removed (FIG. 3L).

(8) A one-micrometer thickness of Al—Si (1%) layer 12 is deposited by sputtering and a pattern of photoresist 13 is provided for forming electrodes (FIG. 3M). Then, exposed portions of the Al—Si layer 12 are removed by wet etching to form electrodes 14n and 14p. The photoresist 13 is removed (FIG. 3N).

(9) A TiO₂ layer 15 is deposited as an antireflection coating on the SiO₂ layer 16 on the light incident side. Finally, the substrate 1 is separated into solar cell sizes by dicing (FIG. 3O).

According to the embodiment, the light energy lower than the band gap energy is absorbed in the intermediate energy level layer 2 where it excites carriers to move from the intermediate energy level layer 2 to the n+ regions 6 and p+ region 9. This can minimize the loss of the carriers by recombination in the intermediate energy level layer 2. The light energy which exceeds the band gap energy is generally absorbed in the substrate 1 where it excites carriers to move directly to the n+ region 6 and the p+ region 9 without passing across the intermediate energy level layer 2. Accordingly, the loss of the carrier by recombination will significantly be reduced.

FIG. 4 schematically illustrates a cross sectional structure of a second embodiment of the present invention. The second embodiment has an intermediate energy level layer 2 with an electron trap provided on the back side opposite to the light incident side of a substrate thereof where n+ region 6 and p+ region 9 are formed.

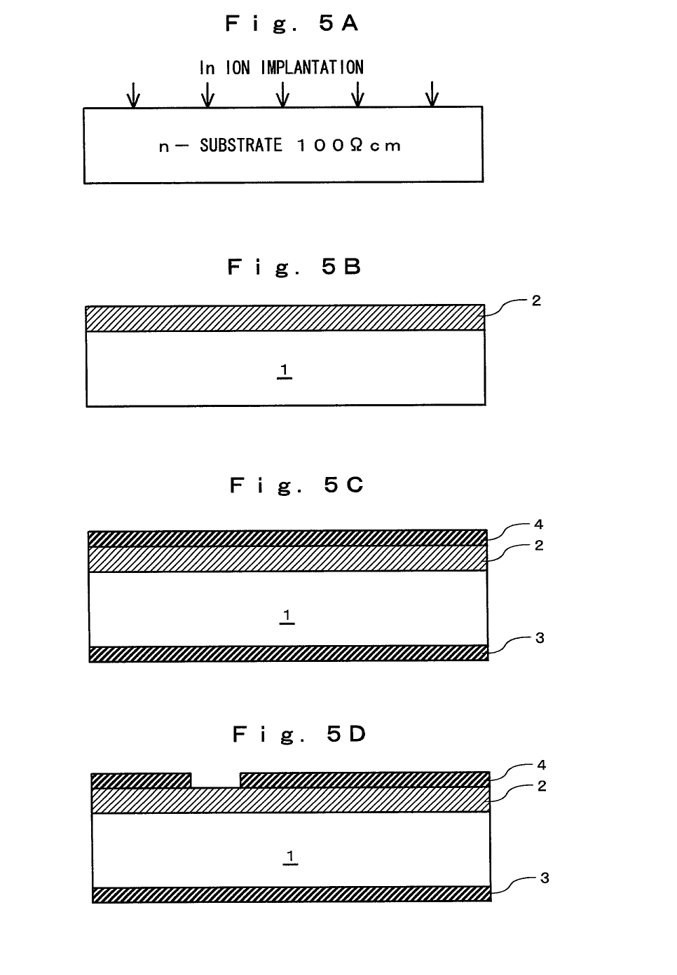

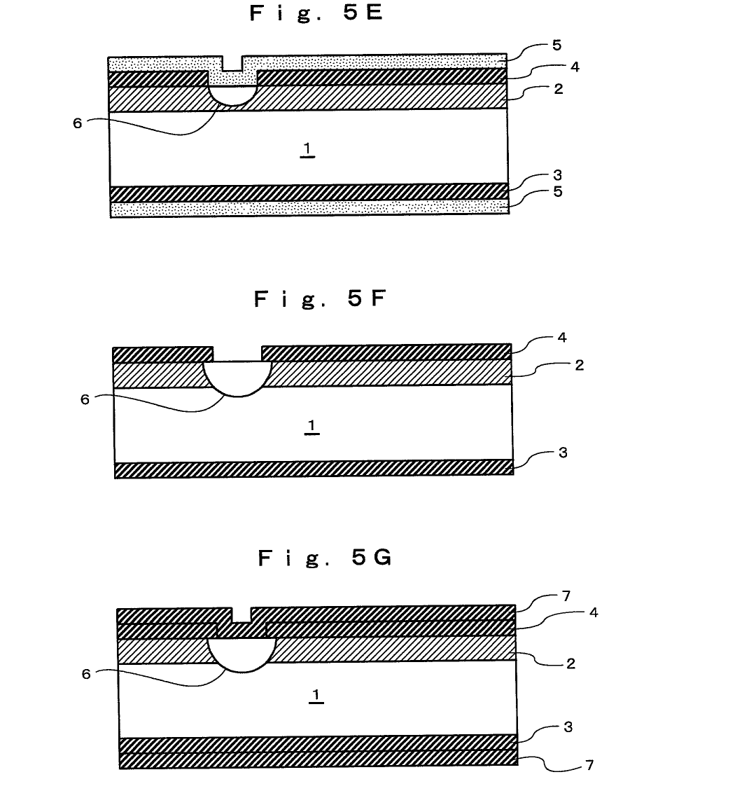

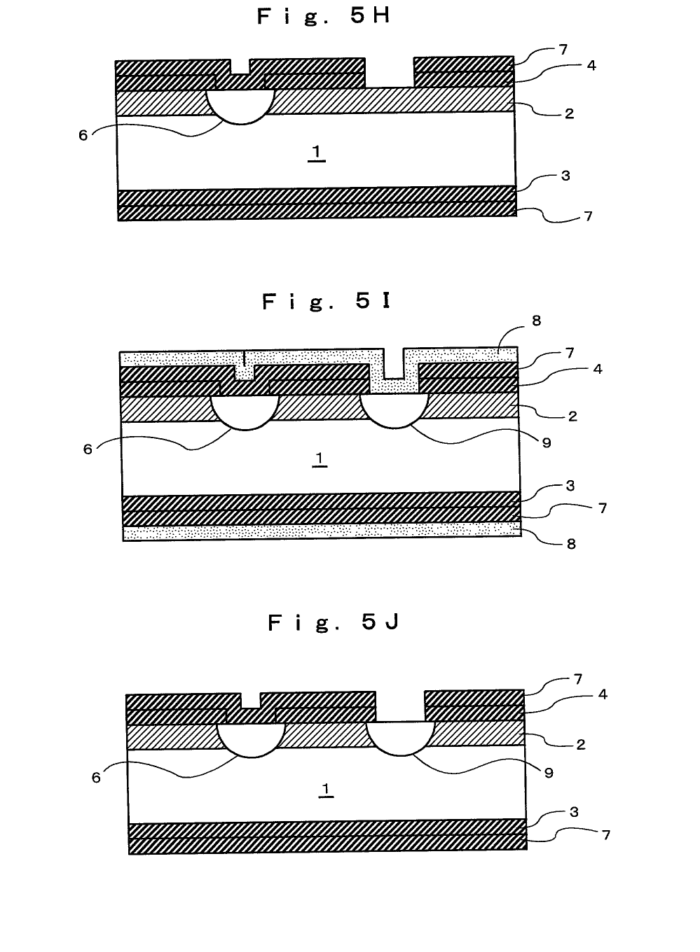

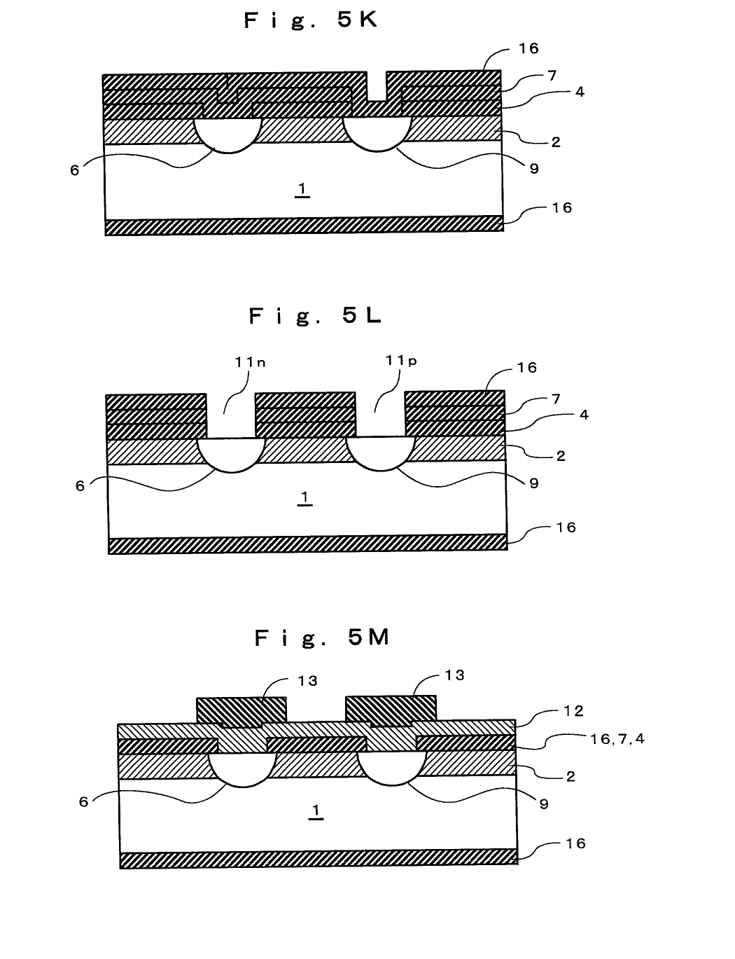

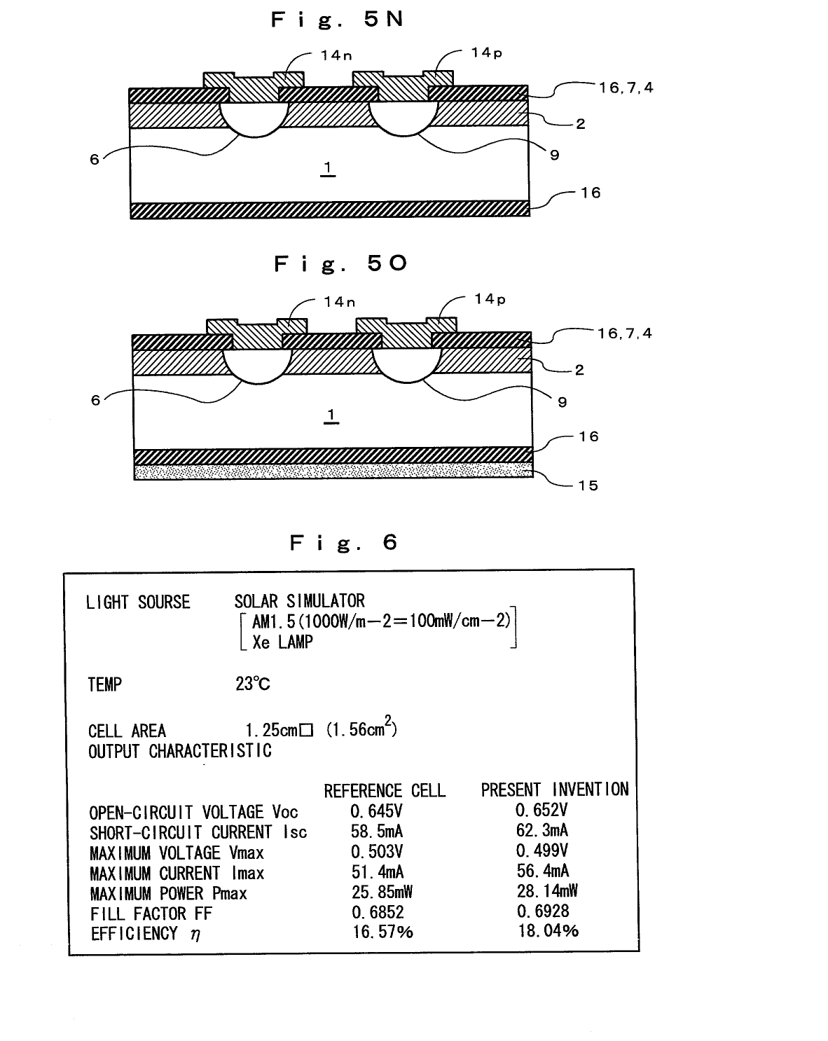

A method of manufacturing the solar cell of the second embodiment will now be described referring to the cross sectional views of FIGS. 5A-5O.

(1) An n− substrate 1 of 100 Ωcm is doped at 180 KV by ion implantation of In of 1E13 cm⁻² (FIG. 5A) and annealed for activation at 1100° C. for two hours to form an intermediate energy level layer 2 in the back side of the light incident side thereof (FIG. 5B).

(2) Thermally oxidized SiO₂ layers 3 and 4 are formed to 500 angstroms on the light incident side and the back side of the substrate 1 respectively (FIG. 5C) and a pattern of photoresist is provided on the back side (not shown). This is followed by wet etching the SiO₂ layer 4 to remove desired portions which will be the n+ regions later (FIG. 5D). At the time, the light incident side remains protected with a film of photoresist (not shown). After the wet etching, all the photoresists are then removed.

(3) A layer of phosphosilicate glass 5 is deposited at 950° C. (FIG. 5E) to diffuse phosphorus to the substrate 1. While the phosphosilicate glass layer 5 is removed using an HF etching solution, its phosphorus is thermally diffused in at 1000° C. to form n+ regions 6 (FIG. 5F). The n+ regions 6 has a depth greater than the thickness of the intermediate energy level layer 2 such that a junction is developed between the n+ region 6 and an n− region in the substrate 1.

(4) Under the same conditions as for forming of the n+ regions 6, thermally oxidized SiO₂ layers 7 are formed to 500 angstroms on both the sides (FIG. 5G). After a pattern of photoresist is provided (not shown), the two SiO₂ layers 4 and 7 are wet etched to remove desired portions which will be the p+ regions later (FIG. 5H). At the time, the light incident side remains protected with a film of photoresist (not shown). After the wet etching, all the photoresists are then removed

(5) A layer of borosilicate glass 8 is deposited at 900° C. and its boron is thermally diffused in at 1000° C. to form p+ regions 9 in the substrate 1 (FIG. 5I). The borosilicate glass layer 8 is removed using the HF etching solution (FIG. 5J). The p+ regions 9 has a depth greater than the thickness of the intermediate energy level layer 2 such that a junction is developed between the p+ region 9 and an n− region in the substrate 1.

(6) The back side is also protected with a film of photoresist (not shown). The two SiO₂ layers 3 and 7 on the light incident side are removed by wet etching with the HF etching solution and then, the photoresist is removed. This is followed by forming on both the sides thermally oxidized SiO₂ layers 16 to 300 angstroms (FIG. 5K).

(7) A pattern of photoresist is provided on the back side for positioning contact holes 11n and 11p (not shown). The SiO₂ layer 16,7 and 4 on the back side is partially removed by wet etching. At the time, the light incident side remains protected with a film of photoresist (not shown). The photoresist is removed (FIG. 5L).

(8) A one-micrometer thickness of Al—Si (1%) layer 12 is deposited on the back side by sputtering and a pattern of photoresist 13 is provided for forming electrodes (FIG. 5M). Then, exposed portions of the Al—Si layer 12 are removed by wet etching to form electrodes 14n and 14p. The photoresist 13 is removed (FIG. 5N).

(9) A TiO₂ layer 15 is deposited as a antireflection coating on the SiO₂ layer 16 on the light incident side. Finally, the substrate is separated into solar cell sizes by dicing (FIG. 5O).

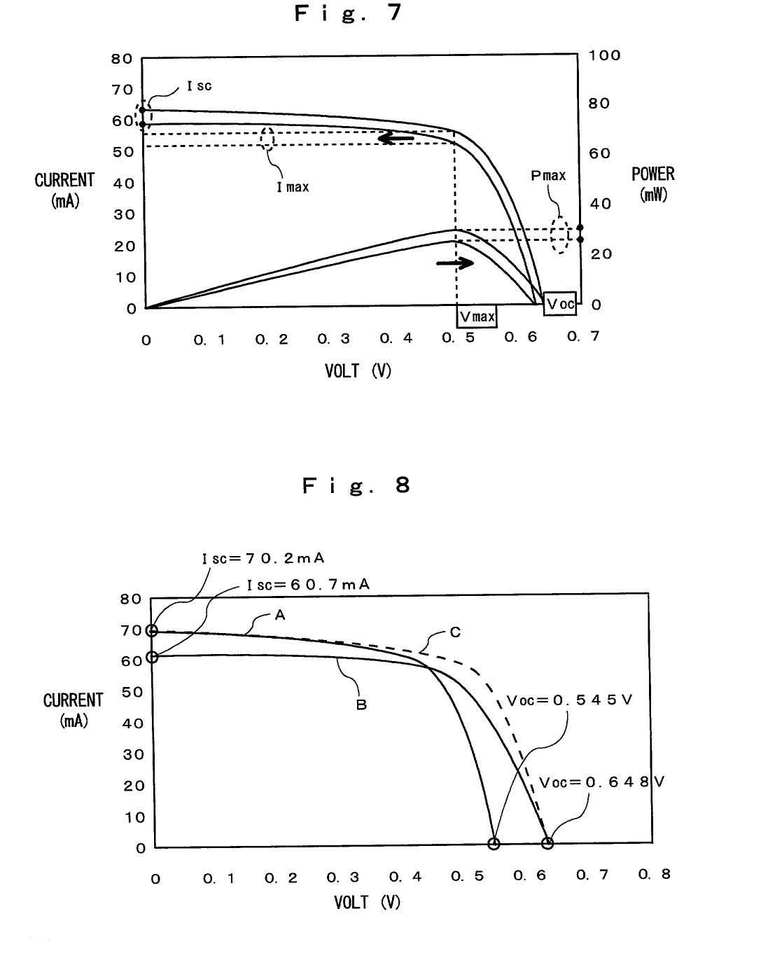

FIG. 6 is a table of the comparison in performance, which is measured by a solar simulator between a solar cell of the second embodiment and a conventional (or reference) solar cell without the intermediate energy level layer. FIG. 7 is a diagram showing the comparison between the current characteristics and the output characteristics. As apparent, the efficiency η of energy conversion in the second embodiment is increased by substantially 9% from 16.57% to 18.04%. This results from the increase of the carriers as is also proved by the fact that the short-circuit current Isc is increased from 58.5 mA to 62.3 mA.

The second embodiment has the intermediate energy level layer 2 doped with impurities so that when located on the same plane as of the n+ regions 6 and the p+ regions 9, the intermediate energy level layer 2 can extend throughout the surface of the substrate before the semiconductor regions 6 and 9 are formed. This allows the intermediate energy level layer 2 to be fabricated without the use of maskings, thus simplifying the overall procedure of the fabrication and contributing to the less complex production of highly durable solar cells.

As the region at the intermediate energy level is not electrically neutral but acts as a donor or acceptor in the semiconductor, it functions as an n type or p type semiconductor. As a result, the leak current may run through the region at the intermediate energy level between the n+ region 6 and the p+ region 9. In FIG. 8, the comparison is illustrated between an IV profile (the curve A) at a higher density of the intermediate level energy and an IV profile (the curve B) at a lower density of the same. As apparent, while the short-circuit current Isc is shifted from 60.7 mA to 70.2 mA by increasing the intermediate level energy, the open-circuit Voc drops down from 0.648 V to 0.545 V. It will hence be difficult to improve the efficiency by increasing the intermediate level energy. In a third embodiment of the present invention described below, the leak current through the intermediate energy level layer is inhibited for allowing the increase of the intermediate level energy to improve the efficiency.

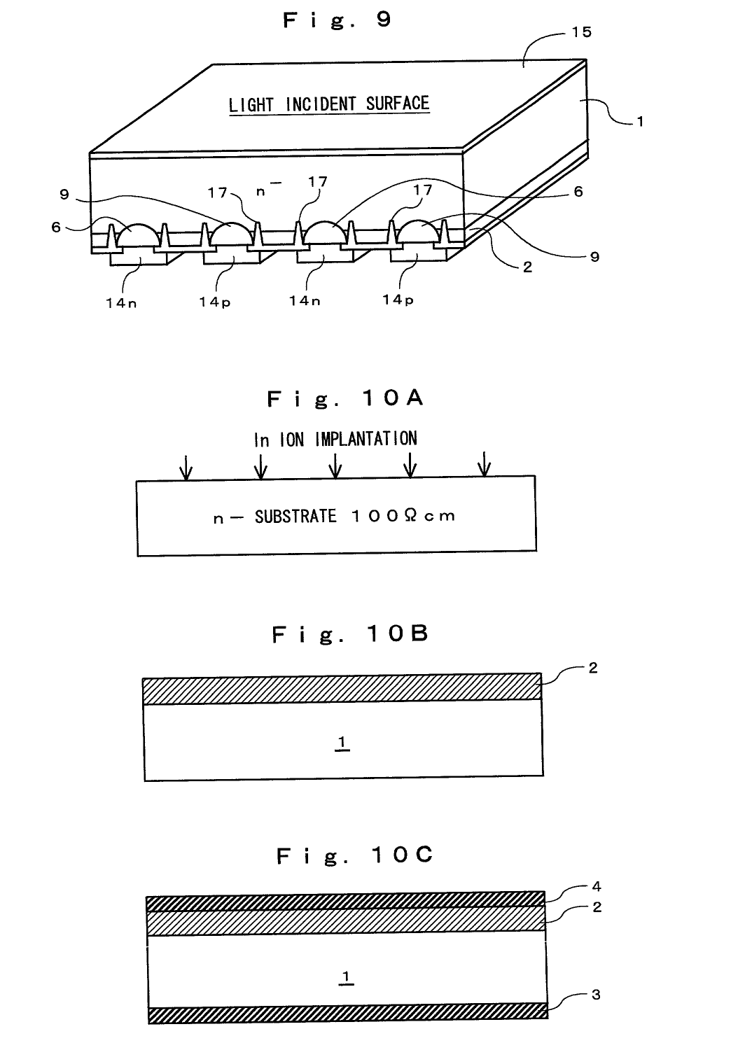

FIG. 9 schematically illustrates a cross sectional structure of a third embodiment of the present invention. The third embodiment has an intermediate energy level layer 2 with an electron trap provided on the back side opposite to the light incident side of a substrate thereof where n+ region 6 and p+ region 9 are formed. Separating grooves 17 are recessed into the intermediate energy level layer 2 from the back side of the semiconductor.

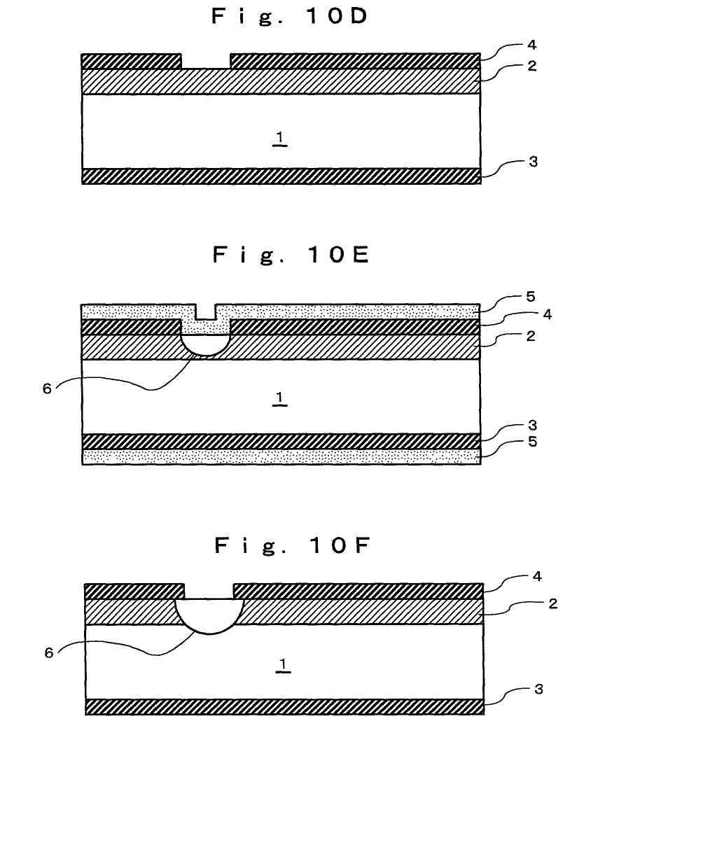

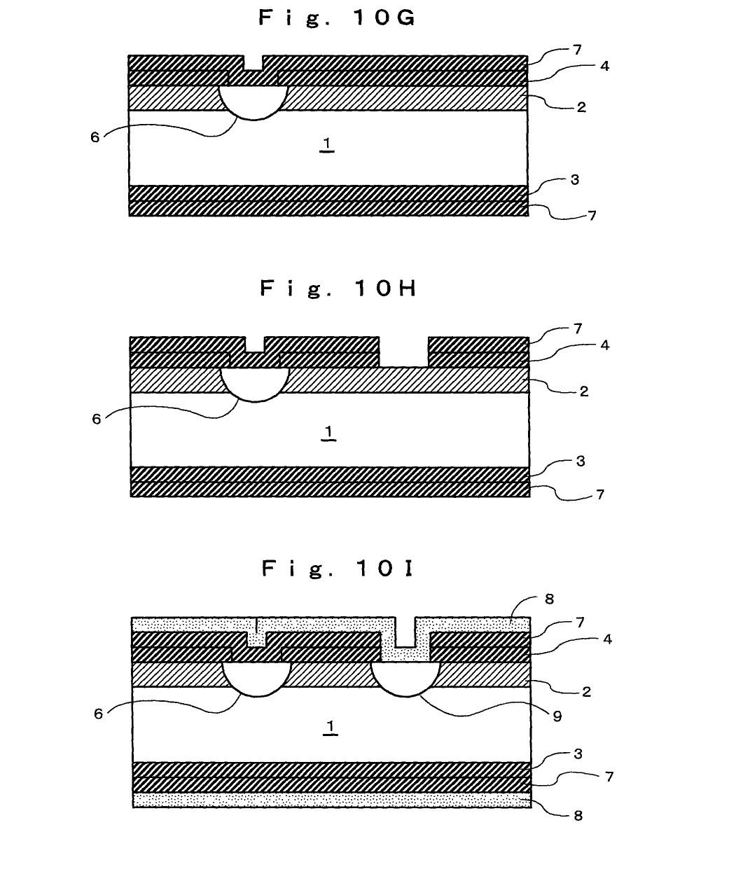

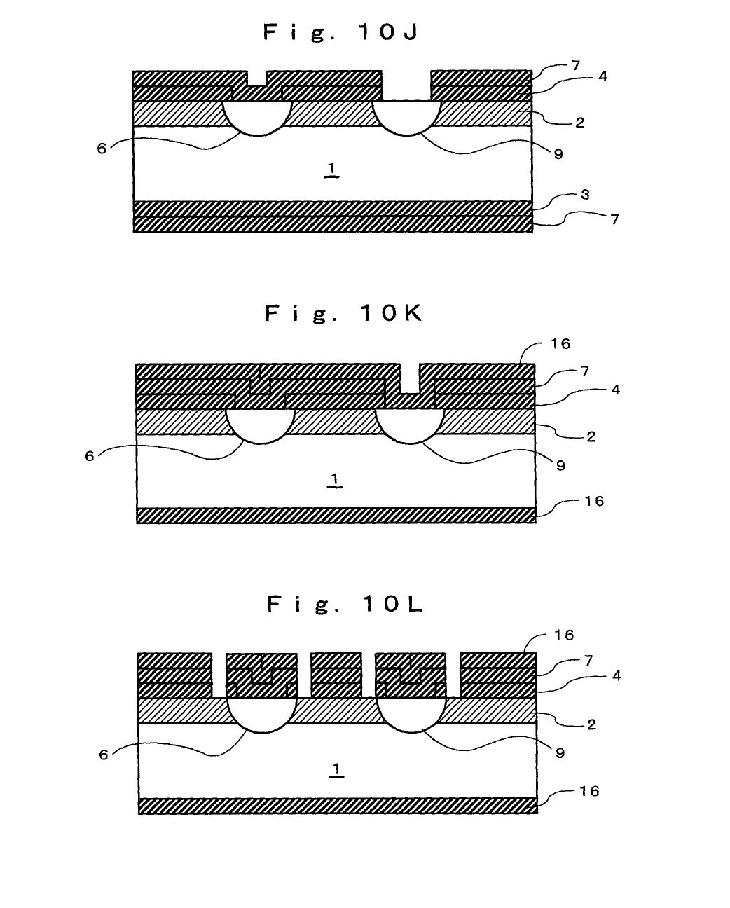

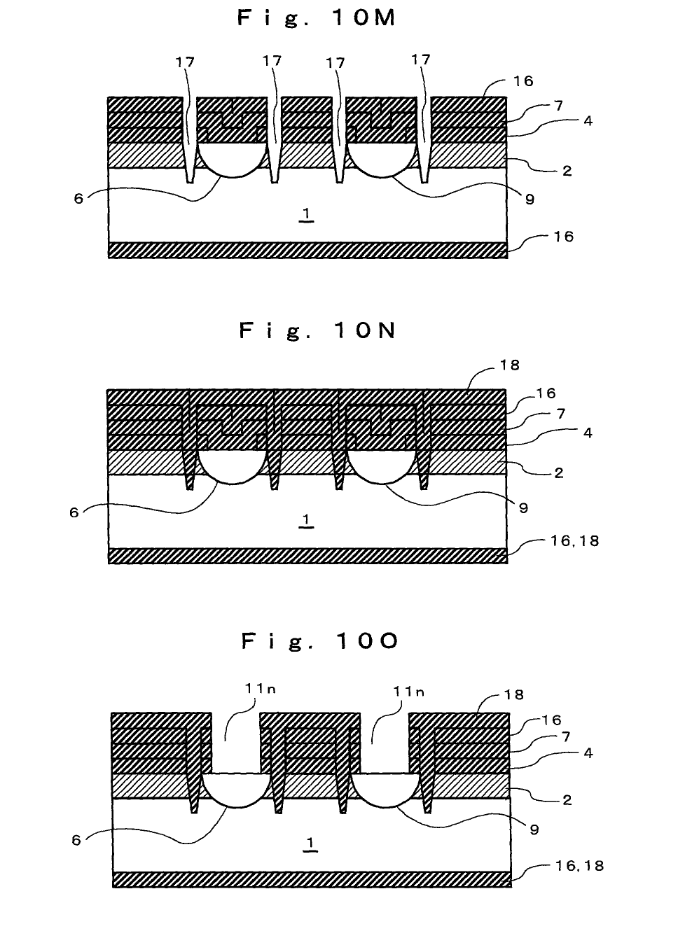

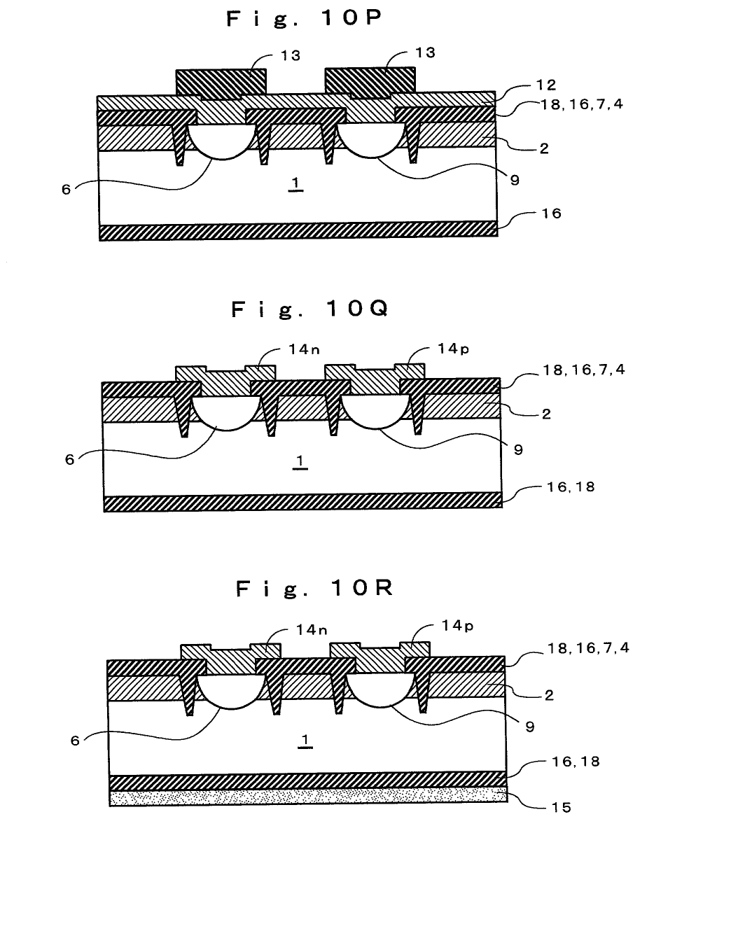

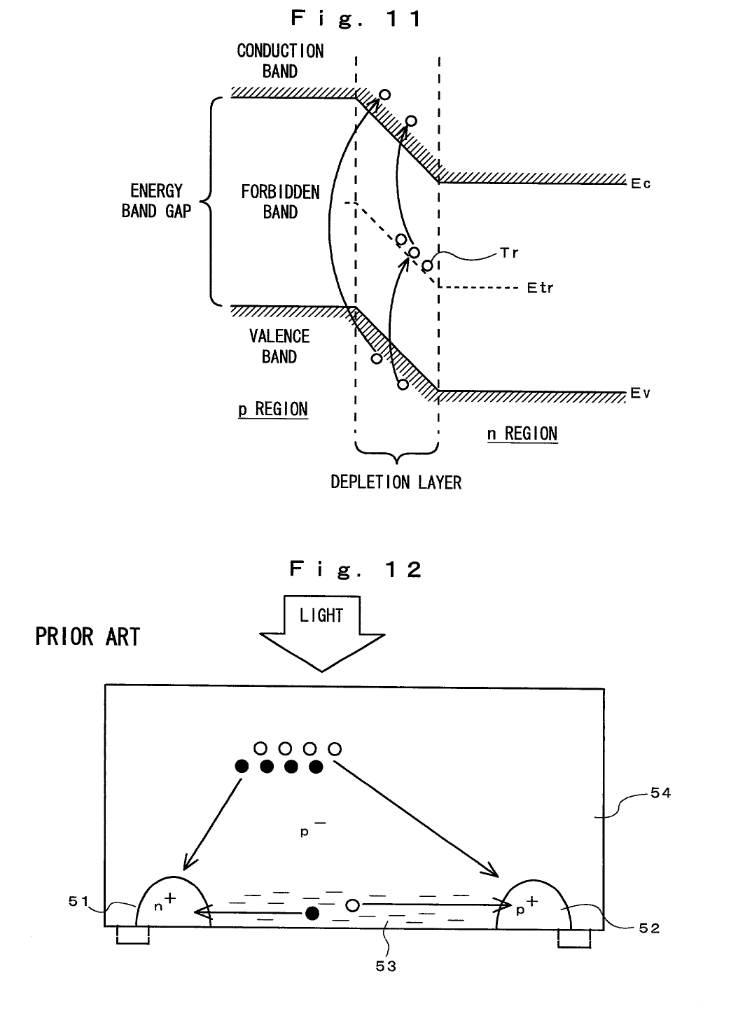

A method of manufacturing the solar cell of the third embodiment will now be described referring to the cross sectional views of FIGS. 10A-10R.

(1) An n− substrate 1 of 100 Ωcm is doped at 180 KV by ion implantation of In of 1E13 cm⁻² (FIG. 10A) and annealed for activation at 1100° C. for two hours to form an intermediate energy level layer 2 in the back side of the light incident side thereof (FIG. 10B).

(2) Thermally oxidized SiO₂ layers 3 and 4 are formed to 500 angstroms on the light incident side and the back side of the substrate 1 respectively (FIG. 10C) and a pattern of photoresist is provided on the back side (not shown). This is followed by wet etching the SiO₂ layer 4 to remove desired portions which will be the n+ regions later (FIG. 10D). At the time, the light incident side remains protected with a film of photoresist (not shown). After the wet etching, all the photoresists are then removed.

(3) A layer of phosphosilicate glass 5 is deposited at 950° (FIG. 10E) to diffuse phosphorus to the substrate 1. While the phosphosilicate glass layer 5 is removed using an HF etching solution, its phosphorus is thermally diffused in at 1000° C. to form n+ regions 6 (FIG. 10F). The n+ regions 6 has a depth greater than the thickness of the intermediate energy level layer 2 such that a junction is developed between the n+ region 6 and an n− region in the substrate 1.

(4) Under the same conditions as for forming of the n+ regions 6, thermally oxidized SiO₂ layers 7 are formed to 500 angstroms on both the sides (FIG. 10G). After a pattern of photoresist is provided (not shown), the two SiO₂ layers 4 and 7 are wet etched to remove desired portions which will be the p+ regions later (FIG. 10H). At the time, the light incident side remains protected with a film of photoresist (not shown). After the wet etching, all the photoresists are then removed.

(5) A layer of borosilicate glass 8 is deposited at 900° C. and its boron is thermally diffused in at 1000° C. to form p+ regions 9 in the substrate 1 (FIG. 10I). The borosilicate glass layer 8 is removed using the HF etching solution (FIG. 10J). The p+ regions 9 has a depth greater than the thickness of the intermediate energy level layer 2 such that a junction is developed between the p+ region 9 and an n− region in the substrate 1.

(6) The back side is also protected with a film of photoresist (not shown). The two SiO₂ layers 3 and 7 on the light incident side are removed by wet etching with the HF etching solution and then, the photoresist is removed. This is followed by forming on both the sides thermally oxidized SiO₂ layers 16 to 300 angstroms (FIG. 10K).

(7) The SiO₂ layer 16 is covered at the surface with a patterned photoresist (not shown) and a group of the SiO₂ layers 16, 7, and 4 are removed by wet etching at two regions between the n+ region 6 and the p+ region 9 (FIG. 10L). Then, exposed portion of the substrate 1 is further etched to provide separating grooves 17 across the intermediate energy level layer 2 at the two regions between the n+ region 6 and the p+ region 9 (FIG. 10M). By oxidizing the substrate, a thermal oxide layer 18 is formed on the substrate and in the separating grooves 17 (FIG. 10N).

(8) With a pattern of photoresist (not shown) applied on the back side of the substrate for providing contact holes 11n and 11p, a group of the SiO₂ layers 18, 16, 7, and 4 are partially wet etched. At the time, the light incident side also remains protected with the photoresist (not shown) Then, the photoresist is removed (FIG. 10O).

(9) A one-micrometer thickness of Al—Si (1%) layer 12 is deposited on the back side by sputtering and a pattern of photoresist 13 is provided for forming electrodes (FIG. 10P). Then, exposed portions of the Al—Si layer 12 are removed by wet etching to form electrodes 14n and 14p. The photoresist 13 is removed (FIG. 10Q).

(10) A TiO₂ layer 15 is deposited as an antireflection coating on the SiO₂ layer 16 on the light incident side. Finally, the substrate is separated into solar cell sizes by dicing (FIG. 10R).

According to this embodiment, the intermediate energy level layer 2 is separated by the separating grooves 17 from the n+ regions 6 and the p+ regions 9, hence developing no current passage between the two regions 6 and 9. This permits the intermediate energy level layer 2 to generate no leak current when its intermediate level energy is increased. Consequently, as denoted by the curve C in FIG. 8, the increase of the intermediate level energy can gain the short-circuit current Isc without declining the open-circuit voltage Voc.

While the intermediate energy level layer 2 with electron trap is doped by ion implantation of indium In as the p-type impurity in each embodiment of the present invention, it may be ion implanted with a n-type impurity such as antimony Sb or the like for canceling the conductivity to prevent the generation of leak current.

The combination of p-type and n-type impurities is not limited to In and Sb but may be between one of B, Al, Ga, and In and one of P, As, and Sb. It may also be feasible for absorbing different wavelengths of the solar light to have two or more different intermediate energy level using multiple impurities.

In the embodiments of the present invention, the ion implantation is used for doping the intermediate energy level layer with impurities and may be replaced by a technique of thermal diffusion to improve the crystalline properties.

What is claimed is:

1. A solar cell having a light incident surface at one side of a semiconductor substrate comprising:
an intermediate energy level layer having electron traps therein and formed over the light incident surface; and
semiconductor regions of a first conductive type and a second conductive type formed in the other side of the semiconductor substrate.

2. A solar cell according to claim 1, wherein the intermediate energy level layer is an impurity doped layer.

3. A solar cell having a light incident surface at one side of a semiconductor substrate comprising:
semiconductor regions of a first conductive type and a second conductive type formed in the other side of the semiconductor substrate; and
an intermediate energy level layer having electron traps therein and formed over the other side of the semiconductor substrate, wherein
the intermediate energy level layer is an impurity doped layer.

4. A solar cell according to claim 3, further comprising separating means for separating the intermediate energy level layer between the semiconductor regions of the first conductive type and the second conductive type.

5. A solar cell according to claim 4, wherein the separating means is a separating groove recessed into the intermediate energy level layer from the other side of the semiconductor substrate.

6. A solar cell according to claim 3, wherein the intermediate energy level layer extends throughout the most of other side of the substrate.

7. A solar cell according to claim 3, wherein the junction of the semiconductor regions of the first conductive type and the second conductive type is extended deeper than the intermediate energy level layer.

8. A solar cell according to claim 2, wherein the intermediate energy level layer includes impurities of the first conductive type and the second conductive type.

9. A solar cell according to claim 3, wherein the intermediate energy level layer includes impurities of the first conductive type and the second conductive type.

10. A solar cell according to claim 8, wherein the intermediate energy level layer is set electrically neutral by controlling the dose of each impurities.

11. A solar cell according to claim 9, wherein the intermediate energy level layer is set electrically neutral by controlling the dose of each impurities.

12. A method of manufacturing a solar cell comprising the steps of:
doping one of two sides of a semiconductor substrate with an amount of impurity to form an intermediate energy level layer having electron traps therein;
doping the other side of the semiconductor substrate with impurities of a first conductive type and a second conductive type respectively to form first conductive regions and second conductive regions; and
providing and connecting external electrodes to the first conductive regions and the second conductive regions.

13. A method of manufacturing a solar cell comprising the steps of:
doping one of two sides of a semiconductor substrate with an amount of impurity to form an intermediate energy level layer having electron traps therein;
doping the side of the semiconductor substrate, where the intermediate energy level layer is formed, with impurities of a first conductive type and a second conductive type respectively to form first conductive regions and second conductive regions; and
providing and connecting external electrodes to the first conductive regions and the second conductive regions.

14. A method of manufacturing a solar cell according to claim 13, further comprising a step of separating the intermediate energy level layer between the semiconductor regions of the first conductive type and the second conductive type.

15. A method of manufacturing a solar cell according to claim 14, wherein the step of separating involves etchig separating grooves into the intermediate energy level layer from the side of the semiconductor substrate.

16. A method of manufacturing a solar cell according to claim 13, wherein the junction of the first conductive regions and the second conductive regions are extended deeper than the intermediate energy level layer.
